(19) United States
(12) Patent Application Publication
(10) Pub. No.: US 2009/0278560 A1
(43) Pub. Date: Nov. 12, 2009

(54) CIRCUIT BOARD TEST CLAMP

(75) Inventors: YUE-BING LI, Shenzhen City (CN); FA-SHENG HUANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/173,753

(22) Filed: Jul. 15, 2008

(30) Foreign Application Priority Data
May 7, 2008 (CN) 200810301461.7

(51) Int. Cl. G01R 31/28

(52) U.S. Cl. 324/755

(57) ABSTRACT

A circuit board test clamp includes a clamping element, and at least one test element. The clamping element includes two clamping boards and a elastic connecting portion integrally formed. The least one test elements each includes a probe and a test connector. The connecting portion connects two end portions of the clamping board. Opposite clamping ends of the clamping board resiliently meet to provide clamping force. At least one test elements are formed on the clamping board; wherein upon a condition that the circuit board is clamped by the clamping element, the test probe is capable of electrically contacting a test point of the circuit board, and the test connector is capable of electrically connecting to the probe of the tester.

### CROSS-REFERENCE TO RELATED APPLICATION

Relevant subject matter is disclosed in co-pending U.S. patent application entitled “CIRCUIT BOARD TEST CLAMP”, filed on Dec. 29, 2007 with application Ser. No. 11/967,059, and assigned to the same assignee as this application.

### BACKGROUND

1. Field of the Invention

The present invention relates to test apparatuses, and particularly to a test clamp which is used to test a circuit board via a tester.

2. Description of Related Art

Before a circuit board such as a double data rage (DDR) memory is sold, it will be tested. When a circuit board is tested, each test point of the circuit board should be welded to an end of an metal extension line thereon and a test probe applied thereto.

However, this test method has same disadvantages. Firstly, this test method requires metal extension lines be welded to the test points of the circuit board, which is unduly laborious and time-consuming and may damage the circuit board. Secondly, the joints of the extension lines and the test points of the circuit board may be rosin joints, which may influence the test quality.

What is desired, therefore, is to secure a circuit board test which overcomes the above problems.

### BRIEF DESCRIPTION OF THE DRAWINGS

FIG. 1 is a schematic plan view of a circuit board test clamp in accordance with a first embodiment of the present invention;

FIG. 2 is a left side elevational view of FIG. 1;

FIG. 3 is a schematic plan view of the circuit board test clamp of FIG. 1 clamping a circuit board;

FIG. 4 is a left side elevational view of FIG. 3;

FIG. 5 is a schematic plan view of the circuit board test clamp of FIG. 3 connected to a probe of a tester;

FIG. 6 is a left side elevational view of FIG. 5;

FIG. 7 is a schematic plan view of a circuit board test clamp in accordance with a second embodiment of the present invention; and

FIG. 8 is a schematic plan view of a circuit board test clamp in accordance with a third embodiment of the present invention.

### DETAILED DESCRIPTION

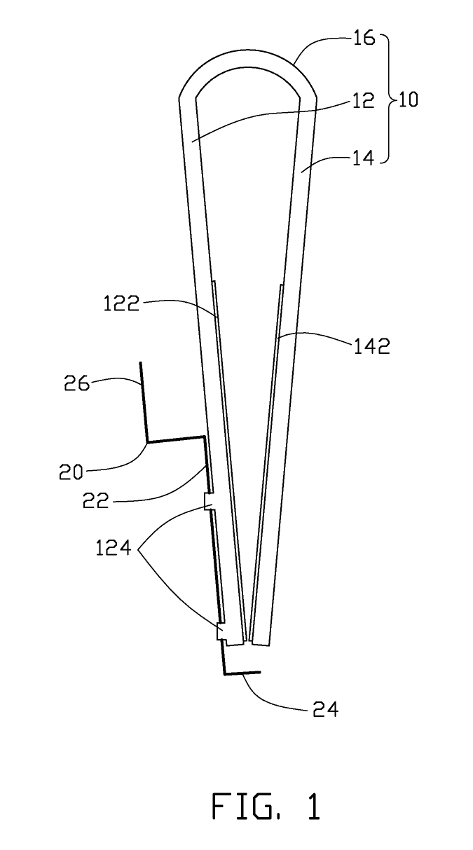

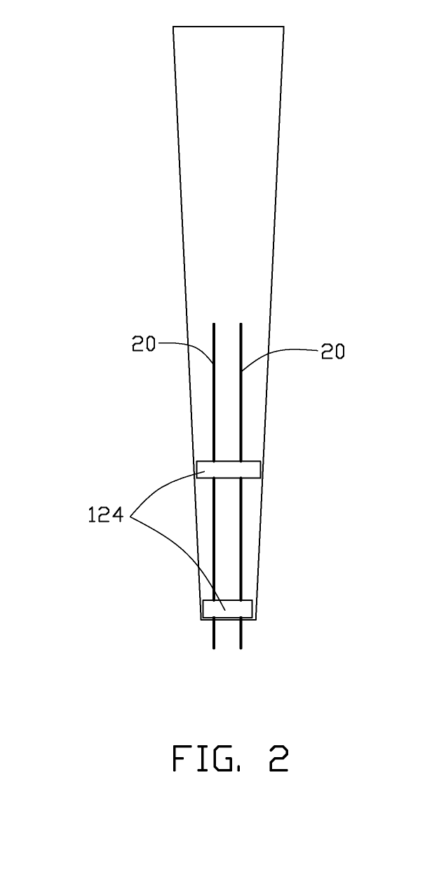

Referring to FIGS. 1 and 2, a circuit board test clamp in accordance with a first embodiment of the present invention includes a clamping element 10, and two test elements 20. The clamping element 10 includes two clamping boards 12, 14, and an elastic connecting portion 16 integrally formed. The connecting portion 16 connects the two clamping boards 12, 14 at one ends of the clamping boards 12, 14 and the opposite ends of the clamping boards 12, 14 resiliently meet to provide clamping force. Two insulating skid pads 122 and 142 are attached on inner sides of the two clamping boards 12 and 14 respectively. The two test elements 20 are formed in parallel on the clamping board 12 via two mounting elements 124.

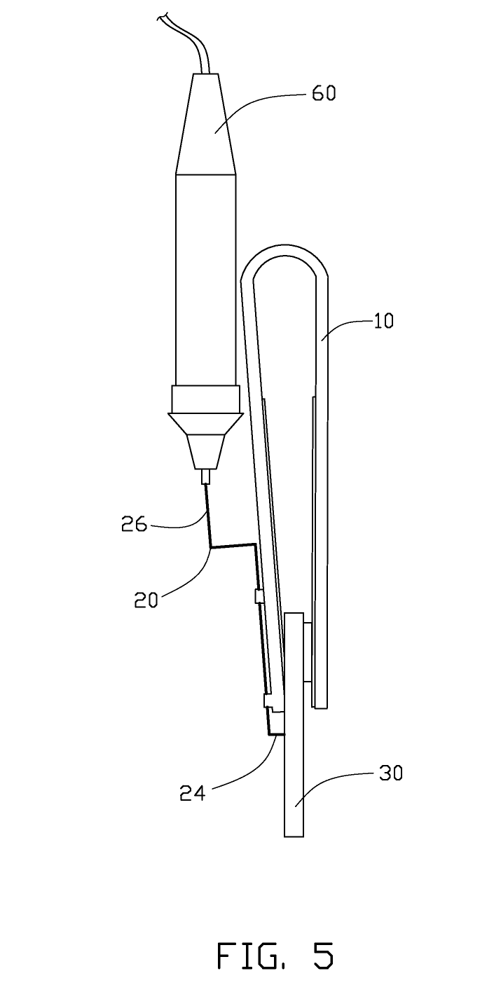

In this embodiment, the test elements 20 each include a connecting element 22 and a L-shaped test probe 24, and a connector 26. The test probe 24 and the connector 26 extend from opposite ends thereof. The test probe 24 is spaced from the clamping ends of clamping boards 12, 14 to facilitate contacting a test point of a circuit board 30 (see FIG. 5). The test connector 26 is spaced from a middle of the clamping board 12, for electrically connecting to a probe of a tester.

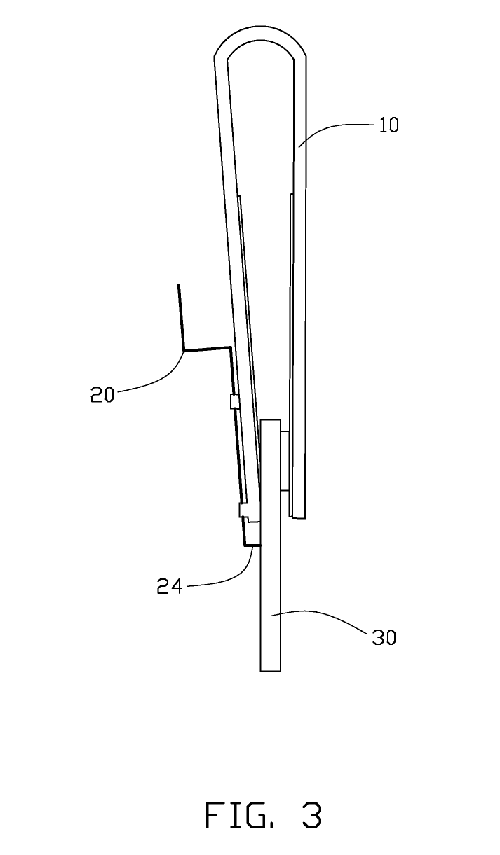

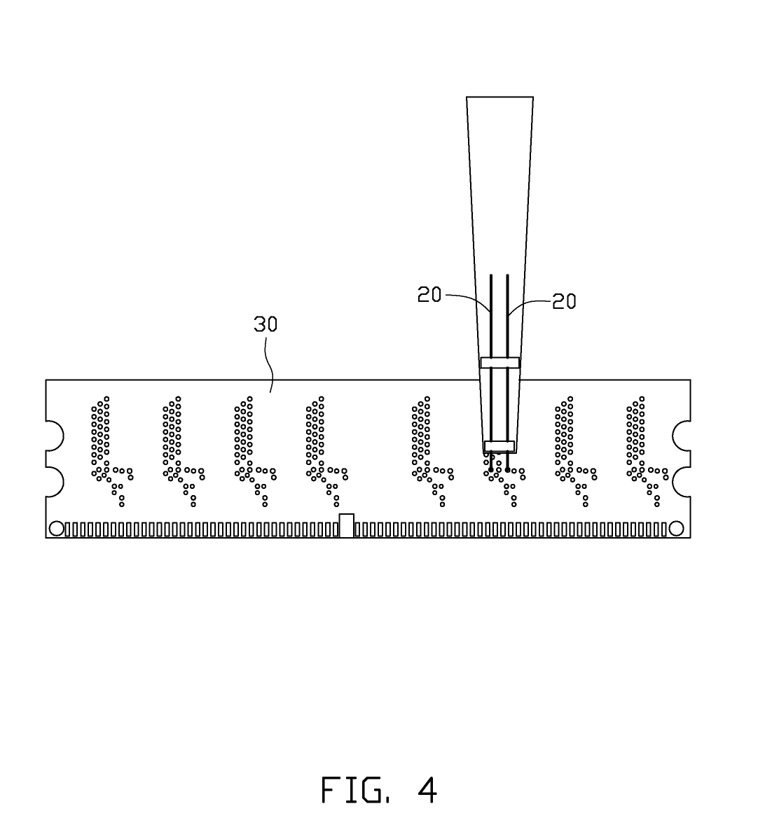

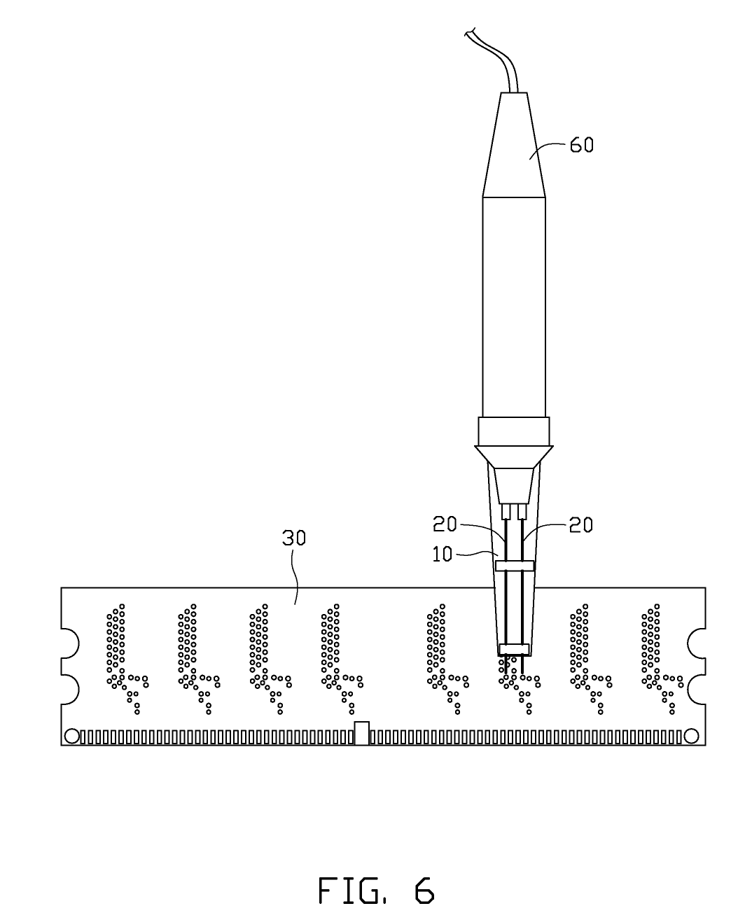

Referring also to FIGS. 3 to 6, in testing two signal terminals of a circuit board 30, the board 30 is received between the two clamping boards 12, and 14. The two probes 24 are connected to the two signal terminals of the circuit board 30. And then, a probe 60 of a tester is electrically connected to the test probes 26, thereby the tester can test the two signal terminals of the circuit board 30. Naturally, if it is desired to test only one signal terminal then only one test element 20 need be used.

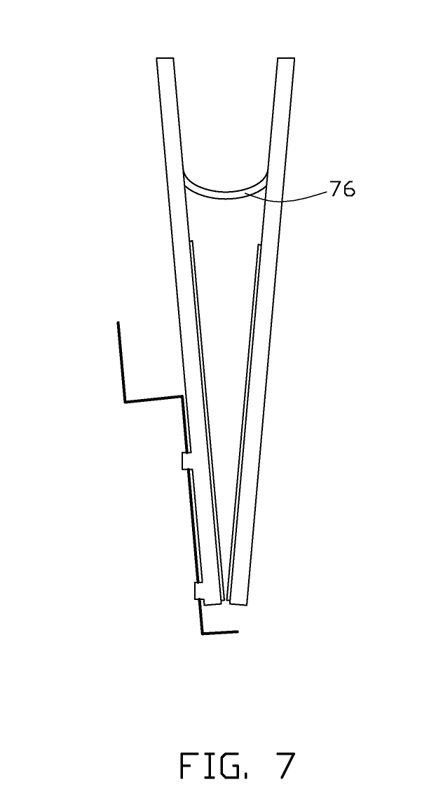

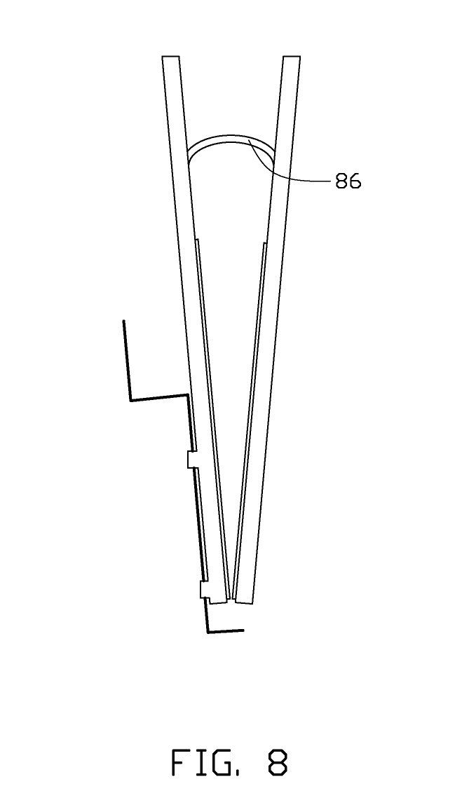

Referring also to FIGS. 7 and 8, a resilient connecting portion 76 replaces the resilient connecting portion 16 in the second embodiment. The connecting portion 76 is arc shaped to provide resiliency and placed between the clamping boards rather than at the ends. The connecting portion 76 is arced towards the clamping ends. In FIG. 8, a connecting portion 86 replaces the connecting portion 76 with the only difference being that the portion 86 is arced away from the clamping ends.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A circuit board test clamp, the circuit board test clamp comprising:
a clamping element configured to clamp on a circuit board, the clamping element comprising two clamping boards and a elastic connecting portion, the connecting portion biases to end portions of the two clamping boards towards each other; and
at least one test element mounted on one of the two clamping boards, the at least one test element comprising a first test probe and a second test connector;
wherein upon a condition that the circuit board is clamped by the clamping element, the first test probe is capable of electrically contacting a test point of the circuit board, and the second test probe is capable of transmitting signals to an external device.

2. The circuit board test clamp as claimed in claim 1, wherein the connecting portion is integrally formed with distal ends of the two clamping boards.

3. The circuit board test clamp as claimed in claim 1, wherein the connecting portion is arced towards the clamping ends.

4. The circuit board test clamp as claimed in claim 1, wherein the connecting portion is arced away from the clamping ends.

5. The circuit board test clamp as claimed in claim 1, wherein the connecting portion is placed between the clamping boards.

6. The circuit board test clamp as claimed in claim 5, wherein the connecting portion is arced towards the clamping ends.

7. The circuit board test clamp as claimed in claim 2, wherein the connecting portion is arced away from the clamping ends.

8. The circuit board test clamp as claimed in claim 1, wherein an insulating skid pads is located on the inner side of each of the clamping boards.
